(19) United States
(12) Patent Application Publication
(10) Pub. No.: US 2026/0293629 A1
(43) Pub. Date: Sep. 24, 2026

(54) BONDED SEMICONDUCTOR STRUCTURE AND METHOD FOR FORMING THE SAME

(71) Applicant: UNITED MICROELECTRONICS CORP., Hsin-Chu City (TW)

(72) Inventors: Chun-Hung Chen, Tainan City (TW); Chuan-Lan Lin, Chiayi City (TW); Chu-Fu Lin, Kaohsiung City (TW); Teng-Chuan Hu, Tainan City (TW); Min-Shiang Hsu, Kaohsiung City (TW)

(73) Assignee: UNITED MICROELECTRONICS CORP., Hsin-Chu City (TW)

(21) Appl. No.: 19/181,366

(22) Filed: Apr. 17, 2025

(30) Foreign Application Priority Data
Mar. 19, 2025 (TW) 114110219

(51) Int. Cl. H10W 20/00; H10W 20/20; H10W 90/00; H10W 90/20; H10W 90/26

(52) U.S. Cl. CPC H10W 20/023; H10W 20/033; H10W 20/076; H10W 20/088; H10W 20/20; H10W 90/00; H10W 90/26; H10W 90/297; H10W 90/732

(57) ABSTRACT

A bonded semiconductor structure includes a first wafer having a first through silicon via (TSV), a second wafer bonded to the first wafer, and a second TSV through the second wafer. The second TSV has a lower portion contacting and electrically connected to the first TSV and an upper portion on the lower portion. A sidewall of the lower portion, a bottom surface and a sidewall of the upper portion form a step-profile.

### BACKGROUND OF THE INVENTION

### 1. Field of the Invention

The invention relates to a bonded semiconductor structure and a method for forming the same, particularly to a bonded semiconductor structure involving through-silicon vias and a method for forming the same.

### 2. Description of the Prior Art

Three-dimensional integrated circuit (3D IC) technology involves stacking multiple two-dimensional die components to form a stacked three-dimensional integrated circuit chip, which may achieve efficient utilization of space, smaller chip package sizes, shorter signal transmission distances between die components, and lower interconnecting resistances. Therefore, 3D IC has gradually become the mainstream technology for a variety of applications such as power converters, low noise amplifiers, radio frequency (RF) or millimeter wave (MMW) components.

Wafer-level bonding is a key technology for achieving high stacking density and heterogeneous integration of functional die components in a 3D IC chip. How to manufacture a chip with more stacked wafers, improve bonding strength between wafers and alignment accuracy between through-silicon/through-substrate vias to interconnect the circuits between the upper and lower wafers successfully are objectives earnestly studied in the field.

### SUMMARY OF THE INVENTION

One embodiment of the invention provides a bonded semiconductor structure that includes a first wafer having a first through silicon via (TSV), a second wafer bonded to the first wafer, and a second TSV through the second wafer. The second TSV has a lower portion contacting and electrically connected to the first TSV and an upper portion on the lower portion. A sidewall of the lower portion, a bottom surface and a sidewall of the upper portion form a step-profile.

Another embodiment of the invention provides a method for forming a bonded semiconductor structure. The method includes the steps of providing a first wafer comprising a first through silicon via (TSV), bonding a second wafer on the first wafer, performing a first etching process to form a via hole stop on an etching stop layer in the second wafer, performing a second etching process to extend the via hole through the etching stop layer and the second wafer to expose a top surface and a sidewall of a interconnecting structure in the second wafer and a top surface of the first TSV, and forming a second TSV in the via hole.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 8 are schematic cross-sectional diagrams illustrating the manufacturing steps of a method for forming a bonded semiconductor structure according to an embodiment of the present invention.

FIG. 9 is a schematic cross-sectional diagram showing a bonded semiconductor structure according to an embodiment of the present invention.

FIG. 10 is a schematic cross-sectional diagram showing a bonded semiconductor structure according to an embodiment of the present invention.

### DETAILED DESCRIPTION

In order to facilitate one of ordinary skills in the art to clearly understand this invention, several exemplary embodiments of the present invention will be detailed as follows, with reference to the accompanying drawings using numbered elements to elaborate the contents and effects to be achieved. The accompanying drawings are included to provide a further understanding of the embodiments, and are incorporated in and constitute a part of this specification. These embodiments are described in sufficient detail to enable those skilled in the art to practice the invention. Structural, logical and electrical changes may be made to the embodiments without departing from the spirit and scope of the present invention. Features from different embodiments may be substituted, interchanged or combined to create other embodiments.

The drawings are simplified and only depict a part of the semiconductor structure. The components in the drawings are not drawn to scale. The numbers and dimensions of the components shown in the drawings are for illustrative purpose only and are not intent to limit the scope of this invention. The spatially relative terms such as“beneath”, “below”, “under’, “lower”, “above”, “upper”, “on”, “over” and the like may be used herein to describe the spatial relationship of one component or feature to another component(s) or feature(s) as illustrated in the drawings. The spatially relative terms are intended to encompass different orientations of the semiconductor structure in addition to the orientation depicted in the drawings. The semiconductor structure may be otherwise oriented (rotated 90 degrees or at other orientations) and the spatially relative descriptors used herein may likewise be interpreted accordingly.

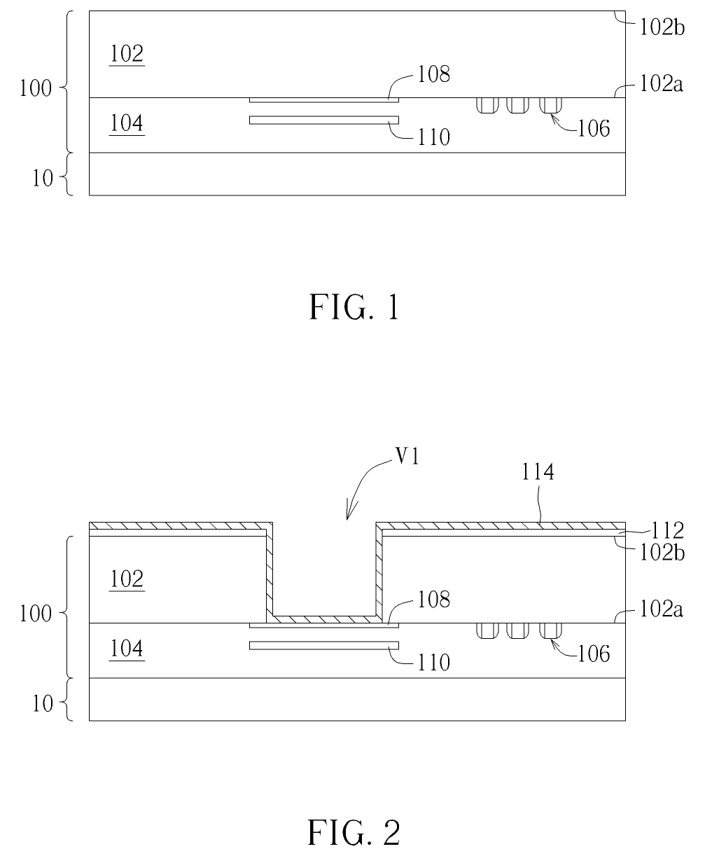

FIGS. 1 to 8 are schematic cross-sectional diagrams illustrating the manufacturing steps of a method for forming a bonded semiconductor structure according to an embodiment of the present invention. As shown in FIG. 1, a first wafer 100 is provided. The first wafer 100 includes a substrate 102 having a front surface 102a and a back surface 102b. A plurality of semiconductor devices 106 and an interconnection layer 104 are formed on the front surface 102a of the substrate 102. The substrate 102 is composed of a semiconductor material. The substrate 102 may include a silicon substrate, a silicon-on-insulator (SOI) substrate, a silicon-germanium substrate, a group III-V semiconductor substrate, or a substrate composed of other suitable semiconductor materials. In some embodiments, the substrate 102 may be composed of non-conductive materials, such as glass or plastic, or may be a sapphire wafer. The semiconductor devices 106 may include transistors, diodes, capacitors, inductors, resistors, and/or any other types of active or passive electrical components, but are not limited thereto. The interconnection layer 104 includes multiple dielectric material layers and conductive layers, conductive structures, and conductive vias formed in the dielectric material layers. In some embodiments, the interconnection layer 104 may further include circuit elements such as capacitors, inductors, resistors, embedded memory, but are not limited thereto. The drawings are simplified and only depict the conductive structure 110 of the interconnection layer 104 which is configured to electrical connect the first through-silicon via (TSV) 120 (shown in FIG. 4). The dielectric materials suitable for composing the interconnection layer 104 may include silicon oxide (SiO2), silicon nitride (SiN), silicon oxynitride (SiON), silicon carbonitride (SiCN), nitride doped silicon carbide (NDC), low-k dielectric materials such as fluorinated silica glass (FSG), hydrogenated silicon oxycarbide (SiCOH), spin-on glass, porous low-k dielectric materials, organic polymer dielectric materials, or other suitable dielectric materials. The conductive materials suitable for composing the conductive structure 110 may include metals such as copper (Cu), aluminum (Al), tungsten (W), titanium (Ti), titanium nitride (TiN), tantalum (Ta), or tantalum nitride (TaN), a compound, composite layer or an alloy of the above materials, but are not limited thereto. The conductive structure 110 may be disposed in any of the dielectric layers of the interconnection layer 104. According to one embodiment of the present invention, the conductive structure 110 is disposed in a first metal layer of the interconnection layer 104. In other embodiments, the conductive structure 110 may be disposed in a second metal layer, a third metal layer, or any suitable metal layer of the interconnection layer 104 according to design requirements.

According to an embodiment of the present invention, an etching stop layer 108 may be disposed on the front surface 102a of the substrate 102. The etching stop layer 108 at least partially overlaps the conductive structure 110 in a vertical direction and is separated from the conductive structure 110 by the dielectric layer(s) of the interconnection layer 104. The material of the etching stop layer 108 may include oxide, such as silicon oxide (SiO₂), but is not limited thereto. The vertical direction refers to the wafer stacking direction.

Subsequently, the first wafer 100 is orientated that the front surface 102a of the substrate 102 faces a carrier 10 and is bonded to the carrier 10, thereby forming the bond structure as shown in FIG. 1, wherein the back surface 102b of the substrate 102 faces upward and the interconnection layer 104 is positioned between the substrate 102 and the carrier 10. The carrier 10 may be a semiconductor substrate such as a silicon substrate, an epitaxial silicon substrate, a silicon carbide substrate, or a silicon-on-insulator (SOI) substrate, but is not limited thereto. According to an embodiment of the present invention, the first wafer 100 is bonded to the carrier 10 through oxide bonding between the interconnection layer 104 or a bonding layer (not shown) additionally disposed on the interconnection layer 104 and the carrier 10.

Please refer to FIG. 2. A polishing process may be performed on the back surface 102b of the substrate 102 to reduce the thickness of the substrate 102. After that, a pad layer 112 is formed on the back surface 102b, and a first etching process is performed to form an opening V1 that extends through the pad layer 112 and the substrate 102, until stopping at the etching stop layer 108. Subsequently, a liner 114 is formed on the pad layer 112, and conformally covering the sidewalls and bottom surface of the opening V1. According to an embodiment of the present invention, the material of the pad layer 112 may include silicon nitride (SiN), and the material of the liner 114 may include silicon oxide (SiO₂), but is not limited thereto.

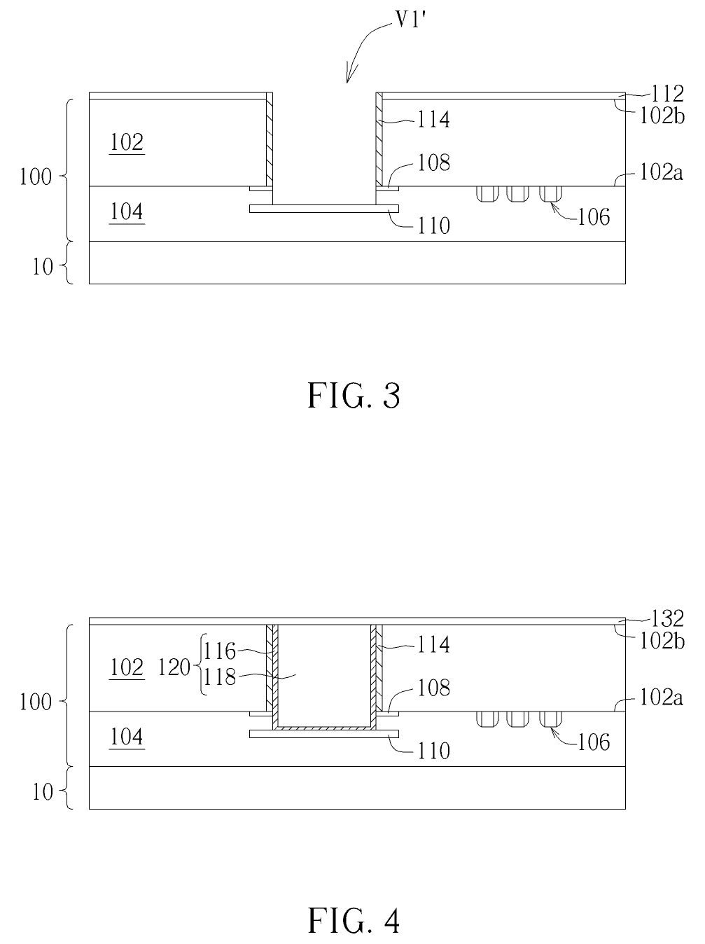

Please refer to FIG. 3. A second etching process is performed, etching through the liner 114, the etching stop layer 108 and the interconnection layer 104 at the bottom of the opening V1, thereby forming the opening V1’ that exposes a portion of the conductive structure 110. It is noteworthy that the portions of the substrate 102 exposed from sidewalls of the opening V1’ remain covered by the liner 114, ensuring the electrical isolation between the substrate 102 and the first TSV 120 subsequently formed in the opening V1’. In some embodiments, the liner 114 on the back surface 102b of the substrate 102 may be removed to expose the pad layer 112 after the second etching process.

Please refer to FIG. 4. A barrier layer 116 is formed and conformally covers the pad layer 112 on the back surface 102b of the substrate 102 and the sidewalls and bottom surface of the opening V1’. Following, a conductive material 118 is formed on the barrier layer 116 and fills the opening V1’. A chemical mechanical polishing (CMP) process is then performed to remove the portions of the conductive material 118 and the barrier layer 116 outside the opening V1', thereby forming a first TSV 120 within the opening V1'. In one embodiment of the present invention, the pad layer 112 may also be removed by the CMP process, and the back surface 102b of the substrate 102 is exposed. The barrier layer 116 may have either a single-layer or multilayer structure. The material of the barrier layer 116 may include tungsten nitride (WN), titanium (Ti), titanium nitride (TiN), tantalum (Ta), tantalum nitride (Ta), or a combination thereof, but is not limited thereto. The conductive material 118 may include metal materials or metal compounds such as copper (Cu), aluminum (Al), tungsten (W), titanium (Ti), titanium nitride (TiN), tantalum (Ta), or tantalum nitride (TaN), but is not limited thereto. In one embodiment of the present invention, the conductive material 118 includes copper (Cu). Optionally, a sputter etching process may be performed to thin or remove the barrier layer 116 on the bottom surface of the opening V1' before forming the conductive material 118, thereby reducing the contact resistance between the first TSV 120 and the conductive structure 110. Subsequently, a bonding dielectric layer 132 is formed and covers the back surface 102b of the substrate 102 and the first TSV 120 in a blanket manner. In one embodiment, the material of the bonding dielectric layer 132 includes silicon carbon nitride (SiCN).

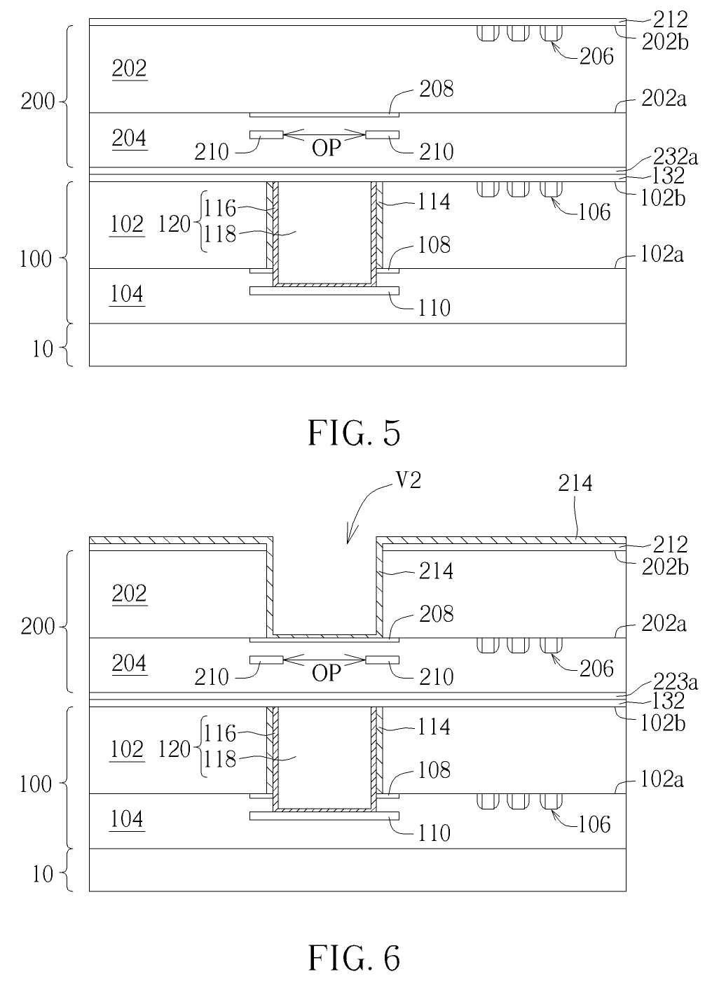

Please refer to FIG. 5. Subsequently, a second wafer 200 is provided and bonded to the first wafer 100. The second wafer 200 includes a substrate 202 having a front surface 202a and a back surface 202b. A plurality of semiconductor devices 206 and an interconnection layer 204 are formed on the front surface 202a of the substrate 202. A bonding dielectric layer 232a is disposed on the interconnection layer 204. The interconnection layer 204 includes multiple dielectric material layers and conductive layers, conductive structures, and conductive vias formed in the dielectric material layers. In some embodiments, the interconnection layer 204 may further include circuit elements such as capacitors, inductors, resistors, embedded memory, but are not limited thereto. The drawings are simplified and only depict the conductive structure 210 of the interconnection layer 204, which is configured to electrical connect the second TSV (shown in FIG. 8). The conductive structure 210 may be disposed in any of the dielectric layers of the interconnection layer 204. According to one embodiment of the present invention, the conductive structure 210 is disposed in a first metal layer of the interconnection layer 204. In other embodiments, the conductive structure 210 may be disposed in a second metal layer, a third metal layer, or any suitable metal layer of the interconnection layer 204 according to design requirements. According to an embodiment of the present invention, an etching stop layer 208 may be disposed on the front surface 202a of the substrate 202. The etching stop layer 208 at least partially overlaps the conductive structure 210 in a vertical direction and is separated from the conductive structure 210 by the dielectric layer(s) of the interconnection layer 204. The materials of the above components of the second wafer 200 may refer to the materials for the first wafer 100 and are not repeated herein for the sake of brevity. Notably, the portion of the conductive structure 210 overlapping with the etching stop layer 208 includes an opening OP. In some embodiments, the opening OP may be a closed opening fully surrounded by the conductive structure 210. In some embodiments, the opening OP may be a non-closed type opening that is partially surrounded by the conductive structure 210.

Please continue to refer to FIG. 5. The first wafer 100 and the second wafer 200 are bonded in the orientation that the front surface 202a of the substrate 202 of the second wafer 200 faces the back surface 102b of the substrate 102 of the first wafer 100, and by the fusion bonding between the bonding dielectric layer 232a and the bonding dielectric layer 132. The opening OP of the conductive structure 210 is aligned directly above the first TSV 120. The width of the opening OP is smaller than the width of the top portion of the first TSV 120.

Please refer to FIG. 6. A polishing process may be performed on the back surface 202b of the substrate 202 to reduce the thickness of the substrate 202. After that, a pad layer 212 is formed on the back surface 202b, and a first etching process is performed to form an opening V2 that extends through the pad layer 212 and the substrate 202 until stopping at the etching stop layer 208. Subsequently, a liner 214 is formed on the pad layer and conformally covering the sidewall and bottom surface of the opening V2. The materials for the pad layer 212 and the liner 214 may refer to the materials for the pad layer 112 and the liner 114, and are not repeated herein for the sake of brevity.

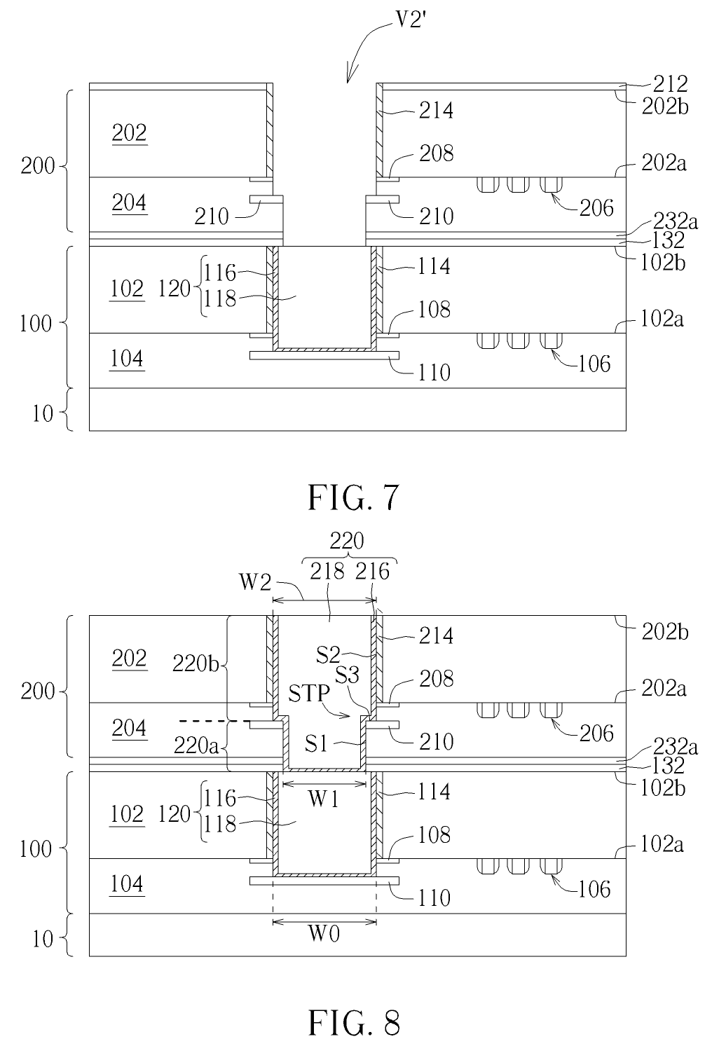

Please refer to FIG. 7. A second etching process is performed, etching through the liner 214, the etching stop layer 208 and the interconnection layer 204 at the bottom of the opening V2 to expose the conductive structure 210 and the opening OP, and then continue etching through the interconnection layer 204, the bonding dielectric layer 232a and the bonding dielectric layer 132 via the opening OP until the top surface of the first TSV 120 is exposed and an opening V2’ is obtained. The opening V2’ extends through the etching stop layer 208 and the second wafer 200 and exposes part of the top surface and sidewalls of the conductive structure 210 and the top surface of the first TSV 120 of the first wafer 100. The portions of the substrate 202 exposed from the sidewalls of the openings V2 remain covered by the liner 214, ensuring the electrical isolation between the substrate 202 and the second TSV 220 subsequently formed in the opening V2’. In some embodiments, the liner 214 on the back surface 202b of the substrate 202 may be removed to expose the pad layer 212 after the second etching process.

Please refer to FIG. 8. A barrier layer 216 is formed to conformally cover the pad layer 212 on the back surface 202b of the substrate 202 and the sidewalls and bottom surface of the opening V2’. Subsequently, a conductive material 218 is formed on the barrier layer 216 and fills the opening V2’. A chemical mechanical polishing (CMP) process is then performed to remove the portions of the conductive material 218 and the barrier layer 216 outside the opening V2', thereby forming a first TSV 220 within the opening V2'. In one embodiment of the present invention, the CMP process may also remove the pad layer 112, exposing the back surface 202b of the substrate 202. The materials of the barrier layer 216 and the conductive material 218 may refer to the materials for the barrier layer 116 and the conductive material 118, and are not repeated herein for the sake of brevity. Optionally, a sputter etching process may be performed to thin or remove the barrier layer 216 on the bottom surface of the opening V2' before forming the conductive material 218, so as to reduce the contact resistance between the second TSV 220 and the first TSV 110.

At this stage, the bonded semiconductor structure of this embodiment is obtained. As shown in FIG. 8, the bonded semiconductor structure includes a first wafer 100 and a second wafer 200. The second wafer 200 is bonded to the first wafer 100 in the orientation that the front surface 202a of the substrate 202 of the second wafer 200 faces the back surface 102b of the substrate 102 of the first wafer 100. A first TSV is disposed in the first wafer 100. A second TSV 220 extends vertically through the second wafer 200 and is aligned directly above the first TSV 120. The second TSV 220 has a monolithic structure, including a lower portion 220a that directly contacts and electrically connects the first TSV 120, and an upper portion 220b located directly on the lower portion 220a. The width W1 of the lower portion 220a is smaller than the width W2 of the upper portion 220b. The sidewall S1 of the lower portion 220a, the bottom surface S3 and the sidewall S2 of the upper portion 220b form a step-profile STP. According to an embodiment of the present invention, the width W1 of the lower portion 220a is also smaller than the width W0 of the first TSV 120. The bottom surface of the first TSV 120 is in direct contact and electrically connected to the conductive structure 110 of the interconnection layer 104 of the first wafer 100, and is further electrically connected to the semiconductor devices 106 and circuit components (not shown) of the first wafer 100 through other conductive structures of the interconnection layer 104. The second TSV 220 is in direct contact and electrically connected to the conductive structure 210 of the interconnect layer 204 of the second wafer 200 through the side wall S1 of the lower portion 220a and the bottom surface S3 of the upper portion 220b, and is further electrically connected to the semiconductor devices 206 and circuit components (not shown) of the second wafer 200 through other conductive structures of the interconnection layer 204. That is, the electrical interconnection between the second TSV220 and the second wafer 200 is achieved by disposing the sidewall portion of the second TSV with the step-profile STP on the conductive structure of the second wafer 200. In comparison with conventional technology that usually forms additional interconnecting layers on the top or bottom of the TSV to interconnect with the wafer, the design of the present invention may simplify the manufacturing steps and reduce the overall thickness of the bonded semiconductor structure.

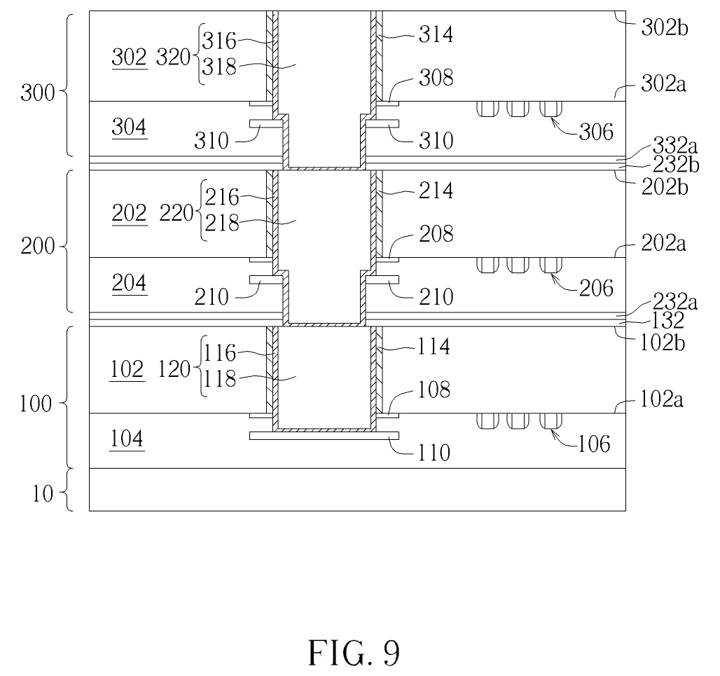

Please refer to FIG. 9, which is a schematic cross-sectional diagram showing a bonded semiconductor structure according to an embodiment of the present invention. The steps from FIGS. 4 to 8 may be repeated to further bond a third wafer 300 on the second wafer 200. The third wafer 300 may have a similar structure to the second wafer 200. For example, the third wafer 300 may include a substrate 302 having a front surface 302a and a back surface 302b. A plurality of semiconductor devices 306 and an interconnection layer 304 are disposed on the front surface 302a of the third wafer 300, and a bonding dielectric layer 332a is disposed on the interconnection layer 304. The interconnection layer 304 includes multiple dielectric material layers and conductive layers, conductive structures, and conductive vias formed in the dielectric material layers. In some embodiments, the interconnection layer 104 may further include circuit elements such as capacitors, inductors, resistors, embedded memory, but are not limited thereto. The drawing is simplified and only depict the conductive structure 310 of the interconnection layer 304 which is configured to electrical connect the third TSV 320. The conductive structure 310 may be disposed in any of the dielectric layers of the interconnection layer 304. According to one embodiment of the present invention, the conductive structure 310 is disposed in a first metal layer of the interconnection layer 304. In other embodiments, the conductive structure 310 may be disposed in a second metal layer, a third metal layer, or any suitable metal layer of the interconnection layer 304 according to design requirements. An etching stop layer 308 may be disposed on the front surface 302a of the substrate 302. The etching stop layer 308 at least partially overlaps the conductive structure 310 in a vertical direction and is separated from the conductive structure 310 by the dielectric layer(s) of the interconnection layer 304.

The process to bond the third wafer 300 and the second wafer 200 may include the following steps. After forming the second TSV 220, a bonding dielectric layer 232b is formed and covers the back surface 202b of the substrate 202 and the second TSV 220 in a blanket manner. Subsequently, the third wafer 300 is provided and bonded to the second wafer 200 in the orientation that the front surface 302a of the substrate 302 of the third wafer 300 faces the second wafer 200, and by the fusion bonding between the bonding dielectric layer 232b and the bonding dielectric layer 332a. Following, a third TSV is 320 is formed and extends vertically through the third wafer 300 and is aligned directly above the second TSV 220. The third TSV 330 includes a barrier layer 316 and a conductive material 318. Similar to the second TSV 220, the third TSV 330 has a monolithic structure, including a narrower lower portion that directly contacts and electrically connects the second TSV 220, a wider upper portion located directly on the lower portion, and a step profile portion between the lower portion and the upper portion, wherein the step profile portion is in direct contact and electrically connected to the conductive structure 310 of the interconnection layer 304, thereby forming electrical interconnection between the third TSV 320 and the third wafer 300. The substrate 302 and the third TSV 320 are separated and electrically isolated by the insulating layer 314. The materials of the components of the third wafer 300 and the third TSV 320 may refer to the materials of the components of the first wafer 100, the second wafer 200, the first TSV 120, or the second TSV 220, and are not repeated herein for the sake of brevity. In some embodiments, the steps from FIGS. 4 to 8 may be repeated to further bond another wafer (not shown) on the third wafer 300 according to design requirements.

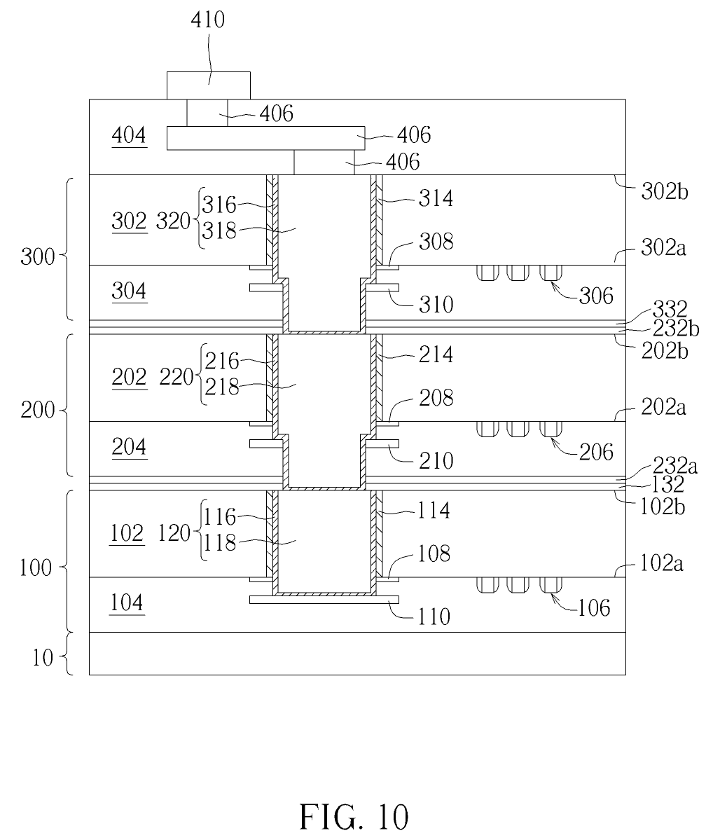

Please refer to FIG. 10, which is a schematic cross-sectional diagram showing a bonded semiconductor structure according to an embodiment of the present invention. After the wafer bonding/stacking process is complete, an interconnection layer 404 and a bonding pad 410 may be formed on the topmost wafer (such as the third wafer 300 in this embodiment), as an external connection terminal of the bonded semiconductor structure. The interconnection layer 404 may have a either single or multiple dielectric material layers and an interconnection structure 406 disposed in the dielectric material layers. The interconnection structure 406 may include conductive layers, conductive structures, and/or conductive vias. The dielectric materials suitable for composing the interconnection layer 404 may include silicon oxide (SiO2) or silicon nitride (SiN), but is not limited thereto. The materials for the interconnection structure 406 and the bonding pad 410 may include metals such as copper (Cu), aluminum (Al), tungsten (W), titanium (Ti), titanium nitride (TiN), tantalum (Ta), or tantalum nitride (TaN), a compound, composite layer or an alloy of the above materials, but are not limited thereto.

In summary, the bonded semiconductor structure and the method for forming the bonded semiconductor structure provided by this invention involve face-to-back bonding wafers and TSV-last process to electrically interconnect the wafers via sidewall of the TSV. The approach of this invention may increase the stacking numbers to provide 3D ICs with higher stacking density.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A bonded semiconductor structure, comprising:
a first wafer comprising a first through silicon via (TSV);
a second wafer bonded to the first wafer; and
a second TSV through the second wafer and comprising:
a lower portion contacting the first TSV; and
an upper portion on the lower portion, wherein a sidewall of the lower portion, a bottom surface and a sidewall of the upper portion form a step-profile.

2. The bonded semiconductor structure according to claim 1, wherein a width of the lower portion of the second TSV is smaller than a width of the upper portion of the second TSV.

3. The bonded semiconductor structure according to claim 1, wherein a width of the lower portion of the second TSV is smaller than a width of the first TSV.

4. The bonded semiconductor structure according to claim 1, further comprising a barrier layer on the sidewall of the lower portion, the bottom surface and the sidewall of the upper portion.

5. The bonded semiconductor structure according to claim 1, further comprising a conductive structure in the second wafer and in direct contact with the sidewall of the lower portion and the bottom surface of the upper portion of the second TSV, wherein the second TSV is electrically connected to the conductive structure and the first TSV.

6. The bonded semiconductor structure according to claim 1, further comprising a bonding dielectric layer between the first wafer and the second wafer and contacting the sidewall of the lower portion of second TSV and a top surface of the first TSV.

7. The bonded semiconductor structure according to claim 1, further comprising an etching stop layer in the second wafer and contacting the sidewall of the upper portion of the second TSV.

8. The bonded semiconductor structure according to claim 1, further comprising a liner on the sidewall of the upper portion of the second TSV.

9. The bonded semiconductor structure according to claim 1, further comprising a bonding pad on the second wafer and electrically connected to the second TSV.

10. The bonded semiconductor structure according to claim 1, further comprising:
a third wafer bonded to the second wafer opposite to the first wafer; and
a third TSV through the third wafer and contacting the second TSV.

11. A method for forming a bonded semiconductor structure, comprising:
providing a first wafer comprising a first through silicon via (TSV);
bonding a second wafer on the first wafer;
performing a first etching process to form a via hole stop on an etching stop layer in the second wafer;
performing a second etching process to extend the via hole through the etching stop layer and the second wafer to expose a top surface and a sidewall of a conductive structure in the second wafer and a top surface of the first TSV; and
forming a second TSV in the via hole.

12. The method according to claim 11, wherein the second TSV comprises:
a lower portion contacting the first TSV; and
an upper portion on the lower portion, wherein a sidewall of the lower portion, a bottom surface and a sidewall of the upper portion form a step-profile.

13. The method according to claim 12, wherein a width of the lower portion of the second TSV is smaller than a width of the upper portion of the second TSV.

14. The method according to claim 12, wherein a width of the lower portion of the second TSV is smaller than a width of the first TSV.

15. The method according to claim 11, further comprising forming a liner on a sidewall of the via hole before performing the second etching process.

16. The method according to claim 11, wherein forming the second TSV comprises:
forming a barrier layer on a sidewall of the via hole; and
forming a conductive material filling the via hole, wherein the barrier layer contacts the top surface and the sidewall of the conductive structure.

17. The method according to claim 11, wherein the second TSV is electrically connected to the conductive structure and the first TSV.

18. The method according to claim 11, wherein the second wafer is bonded to the first wafer by fusion bonding.

19. The method according to claim 11, further comprising forming a bonding pad on the second wafer and overlapping the second TSV.

20. The method according to claim 11, further comprising:
forming a bonding dielectric layer on the second wafer and overlapping the second TSV; and
bonding a third wafer to the second wafer.
